(19) United States
(12) Patent Application Publication
(10) Pub. No.: US 2017/0033187 A1
(43) Pub. Date: Feb. 2, 2017

(54) ENHANCEMENT MODE FIELD EFFECT TRANSISTOR WITH DOPED BUFFER AND DRAIN FIELD PLATE

(71) Applicant: Ohio State Innovation Foundation, Columbus, OH (US)

(72) Inventors: Siddharth Rajan, Columbus, OH (US); Sanyam Bajaj, Columbus, OH (US)

(21) Appl. No.: 15/225,084

(22) Filed: Aug. 1, 2016

Related U.S. Application Data
(60) Provisional application No. 62/199,587, filed on Jul. 31, 2015.

(51) Int. Cl. H01L 29/205; H01L 29/16; H01L 29/20; H01L 27/06; H01L 29/868; H01L 29/861; H01L 23/528; H01L 29/40; H01L 29/778

(52) U.S. Cl. CPC H01L 29/205; H01L 29/404; H01L 29/1608; H01L 29/2003; H01L 29/7787; H01L 29/868; H01L 29/8611; H01L 23/528; H01L 27/0629

(57) ABSTRACT

This disclosure relates to a novel approach towards enhancing the threshold voltage of an enhancement-mode field-effect-transistor (E-mode FET) using doped or polarization-graded buffer layers and utilizing drain-connected field plates to engineer peak fields. Enhancement-mode field effect transistors (E-mode FETs) with doped buffer layers replacing conventional undoped buffer layers could enable larger threshold voltages, owing to higher capacitance from the back. These FETs with larger threshold voltages, however, would experience large operational electric fields near the drain contact. Described herein are embodiments of an E-mode FET further comprised of doped buffer layer(s) in the structure of the HEMT to enable larger positive threshold voltages, with optional one or more drain field plates that modify the electric field profile in the channel of the device and improve device breakdown characteristics.

### CROSS REFERENCE TO RELATED APPLICATION

This application claims priority to and benefit of U.S. Provisional Patent Application Serial No. 62/199,587 filed on Jul. 31, 2015, which is fully incorporated by reference and made a part hereof.

### BACKGROUND

A field-effect transistor (FET), which is a fundamental element of digital integrated-circuits, is comprised of four-terminal architecture (source, gate, drain and body) and functions as a small amplifier to amplify gate signals by modulating the resistance between the source and the drain. In power switching applications, it is desired to have normally-off operation with high threshold voltages for failure-safety, compatibility with the existing gate-drive systems, and better noise tolerance. III-nitride based high electron mobility transistors (HEMT) are suitable candidates for power switching applications, however they may have threshold voltages for normally off operation that are too low for widespread application. Gann based HEMTs have demonstrated normally off operation but with threshold voltages below 3 V. A conventional E-mode HEMT device with an undoped buffer (where the depletion width is much greater than the cap thickness) offers low buffer-capacitance, causing most of the voltage drop across the buffer, which limits Vₜ.

Replacing undoped buffer layers with doped buffer layers in the structure of the HEMT could offer higher capacitance from the back and enable larger threshold voltages. The operational electric field in such a structure is the highest towards the drain contact, and peaks at the drain edge, unlike the undoped case, where the peak lies at the gate edge towards the drain. Drain connected field plates may be added to such an FET in order to reduce the peak electric field and improve the breakdown characteristics.

Therefore, what are needed are devices, systems and methods that overcome challenges in the present art. In particular, devices, systems, methods are desired that improve the threshold voltage in E-mode FETs.

### SUMMARY

Disclosed herein are device, systems and methods of the use of doped or polarization-graded buffer layers below the channel in an E-mode FET design to reduce the back depletion and provide higher buffer-capacitance, which results in higher voltage drop across the cap/barrier layer(s) and prevents applied gate-bias from dropping completely across the depleted buffer. Thus the Vt can be designed and enhanced (positive shift) by adjusting the capacitance of the cap layer, essentially lowering it by incorporating one or more dielectric layers cascaded over gate, or by simply making the gate-dielectric thicker, both resulting in higher potential drop across the cap (higher Vt).

This E-mode design with one or more cascaded dielectric layers could be derived for all material systems, including III-Nitrides. One or more Metal-Dielectric-Metal capacitors can be cascaded using fabrication and deposition techniques such as electron-beam metal evaporation and atomic-layer deposition respectively. Similarly one or more PN or PIN diodes using tunnel junction (TJ) interconnects could be cascaded over an E-mode FET using epitaxial growth techniques such as Molecular Beam Epitaxy and Metal Organic Chemical Vapor Deposition. It is possible to realize low resistance inter-band tunneling in III- nitrides, which has been shown by over the last few years (see, for example, S. Krishnamoorthy, D. N. Nath, F. Akyol, P. S. Park, M. Esposto, and S. Rajan, “Polarization-engineered GaN/InGaN/GaN tunnel diodes,” Appl. Phys. Lett., 97, 203502 (2010); S. Krishnamoorthy, P. S. Park, and S. Rajan, “Demonstration of forward inter-band tunneling in GaN by polarization engineering,” Appl. Phys. Lett., 99, 233504 (2011); S. Krishnamoorthy, F. Akyol, P. S. Park, and S. Rajan, “Low resistance GaN/InGaN/GaN tunnel junctions,” Appl. Phys. Lett. 102, 113503 (2013); and S. Krishnamoorthy, T. F. Kent, J. Yang, Pil Sung Park, R. Myers, S. Rajan, “GdN Nanoisland-Based GaN Tunnel Junctions,” Nano Letters DOI: 10.1021/n14006723 (2013), which are fully incorporated by reference). The diode, TJ pair can be repeated to add capacitance and thus positive threshold voltage.

The operational electric field in such a structure is the highest towards the drain contact, and peaks at the drain edge unlike the undoped case, where the peak occurs at the gate edge towards the drain. Drain connected field plates may be added to such an FET in order to reduce the peak electric field and improve the breakdown characteristics. One or more metal field plates may be stacked over the drain contact, separated by optional dielectric layers, and shaped in the way best to improve the electric field profile in the device, especially across the channel.

One or more field plate layers can be integrated over the drain using any metal deposition techniques, such as evaporation and sputtering. Different metal layers may be designed and interconnected with the drain using any device processing techniques, and may be separated by dielectric layers using any deposition techniques.

Drain connected field plates may be added to the structure of an E-mode FET in order to reduce the peak electric field and improve the breakdown characteristics. One or more metal or doped semiconductor field plates may be stacked over the drain contact, separated by optional dielectric layers, and shaped in the way best to improve the electric field profile in the device, especially across the channel.

In one aspect, an enhancement mode field effect transistor (E-mode FET) is described. One embodiment of the E-mode FET comprises a source contact, a gate contact, a drain contact, a substrate, one or more buffer layers, one or more channel layers, one or more barrier layers, and one or more drain field plates. In one aspect, each of the substrate, one or more buffer layers, one or more channel layers, one or more barrier layers, and one or more drain field plates can be epitaxially grown during the epi-growth or added using other regrowth and/or fabrication techniques. Optionally, the E-mode FET may include a body contact.

In one aspect, the substrate can be comprised of III-nitride based material. In another aspect, the substrate can be comprised of any other commercially available substrate material such as Silicon (Si), Silicon Carbide (SiC), Sapphire, and the like.

In one aspect, the one or more buffer layers can be comprised of one or more Aluminum Indium Gallium Nitride (AlInGaN) layers with any compositions, doping or composition-grading to achieve normally-off operation or enhance the threshold voltage of the device.

In one aspect, at least one of the one or more buffer layers has an opposite conductivity as at least one of the one or more channel layers. For example, at least one of the one or more buffer layers has p-type conductivity for an n-channel HEMT and vice-versa, wherein the conductivity of the one or more buffer layers or the one or more channel layers can be achieved using any implantation, doping or composition-grading schemes to achieve desired device threshold. The buffer layer(s) may be grown epitaxially beneath the entire device, or patterned under the gate contact using any fabrication or regrowth techniques.

In one aspect, the buffer layer(s) comprise of any techniques such as ion-implantation, impurity doping, polarization-grading, or a combination of one of more methods to achieve normally-off operation.

In one aspect, an ohmic contact can be formed to the opposite conductivity layer(s) from the top, side or bottom of the device; and with or without the use of tunnel junction layer(s) to inject carriers in to the opposite conductivity layer(s).

In one aspect, the one or more channel layers can be comprised of one or more III-N layers with any compositions, doping or grading.

In one aspect, the one or more barrier layers can be comprised of one or more III-N layers (any compositions, doping or grading) and/or one or more dielectric layers.

In one aspect, the one or more drain field plates can be comprised of one or more layers deposited above the drain contact, wherein the drain field plate reduces a peak electric field in the one or more channel layers. In various aspects, the one or more drain field plates can be comprised of metal and/or doped semiconductor materials.

In one aspect, at least one of the one or more drain field plates comprises an overhang structure that at least partially overlaps the drain contact, extending into an access region towards the gate or source contacts. In one aspect, the overhang structure extends over at least one layer of at least one of the drain field plates and comprises additional field plate layers buried under one or more dielectric layers.

In one aspect, at least one of the one or more drain field plates is separated from the drain contact using one or more dielectric layers and interconnected with the drain contact using one or more vias.

In one aspect, at least one of the one or more drain field plates is comprised of any number of drain field plate layers and dielectric layers cascaded over the drain contact, or connected to any other device terminal, such as source, body or gate.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other and like reference numerals designate corresponding parts throughout the several views. The patent or application file contains at least one drawing executed in color. Copies of this patent or patent application publication with color drawing(s) will be provided by the Office upon request and payment of the necessary fee:

FIG. 1 is an overview of the architecture of an exemplary E-mode FET;

FIG. 2 illustrates the architecture of an exemplary E-mode FET, further comprising one or more drain field plates;

FIG. 3 illustrates the architecture of an exemplary E-mode FET, further comprising one or more dielectric layers;

FIG. 4 illustrates the architecture of an exemplary E-mode FET, further comprising one or more dielectric layers and one or more drain field plates;

FIG. 5 illustrates the architecture of an exemplary E-mode FET, further comprising one or more dielectric layers;

FIG. 6 illustrates the architecture of an exemplary E-mode FET, further comprising one or more dielectric layers and one or more drain field plates;

FIG. 7 illustrates the architecture of an exemplary E-mode FET, further comprising one or more dielectric layers and one or more drain field plates;

FIG. 8 illustrates the architecture of an exemplary E-mode FET, further comprising one or more dielectric layers and one or more drain field plates;

FIGS. 9, 10, and 11 are examples of contours illustrating device operational electric field in the x-direction with (FIG. 9) no drain field plates; (FIG. 10) one drain field plate; and (FIG. 11) two drain field plates;

FIG. 12 is an example of a simulated device operational electric field across a two-dimensional electron gas (2DEG) channel in x-direction showing a peak reduction with the use of drain field plates;

FIG. 13 illustrates an exemplary enhancement mode high electron mobility transistor (HEMT);

FIGS. 14A-14N illustrate various non-limiting designs and configurations of a HEMT;

FIG. 15 illustrates the HEMT of FIGS. 13-14N in the equilibrium state and the on state where C_{CAP} and C_{CHANNEL} are the capacitances of the cap and the channel, respectively;

FIG. 16 illustrates a positive shift in the threshold voltage by lowering gate capacitance in an embodiment with a p-type buffer; and

FIGS. 17A and 17B illustrate simulated C-V and ID-VG transfer characteristics of embodiments of the disclose HEMT of FIGS. 13-14N with varying dielectric (cap) thicknesses (5 nm to 40 nm), demonstrating enhancement of threshold voltage with increasing dielectric thickness.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

Described herein are embodiments of enhancement-mode field-effect-transistors (E-mode FETs) comprised of doped or composition-graded buffer layers, and utilizing drain field plates. While using p-type buffer layers in n-channel FETs, or vice versa, can enable high threshold normally-off operations, it results in a high operational electric fields towards the drain contact of the FET. Embodiments of drain connected field plates (i.e., drain field plates) improve the electric field profile in the channel and reduce the peak value at the drain edge, thus enhancing the performance of the FET.

For example, III-nitride based high electron mobility transistors (HEMT) are suitable candidates for power switching applications. GaN based HEMTs have demonstrated normally off operation, but with threshold voltages below 3 V. Replacing an undoped GaN buffer with a p-type doped buffer offers higher capacitance from the back and enables larger threshold voltages. The operational electric field in such a structure is the highest towards the drain contact, and peaks at the drain edge, unlike the undoped case, where the peak lies at the gate edge towards the drain. Drain connected field plates can be added to such a FET in order to reduce the peak electric field and improve the breakdown characteristics. One or more metal and/or doped semiconducting drain field plates may be stacked over the drain contact, separated by optional dielectric layers, and shaped in the way best to improve the electric field profile in the device, especially across the channel.

In one embodiment, the drain field plate is comprised of one or more layers. Each layer may be comprised of a metal such as Titanium, Aluminum, Gold and the like, or a highly doped semiconducting material such as aluminum indium gallium nitride (AlInGaN) layer. One or more drain field plate layers can be integrated over the drain contact using any metal deposition techniques, such as evaporation and sputtering. Different metal layers may be designed and interconnected with the drain using any device processing techniques, and may be separated by dielectric layers using any deposition techniques. Vias can be used to connect the metal layers with the drain contact. Similarly, drain field plate layers comprised of semiconducting material can be epitaxially grown during the epi-growth or added using other regrowth and/or fabrication techniques. The semiconductor drain field plate layers can be doped or composition-graded using any implantation, doping or grading schemes. Vias may also be used to connect the semiconductor layers with the drain contact.

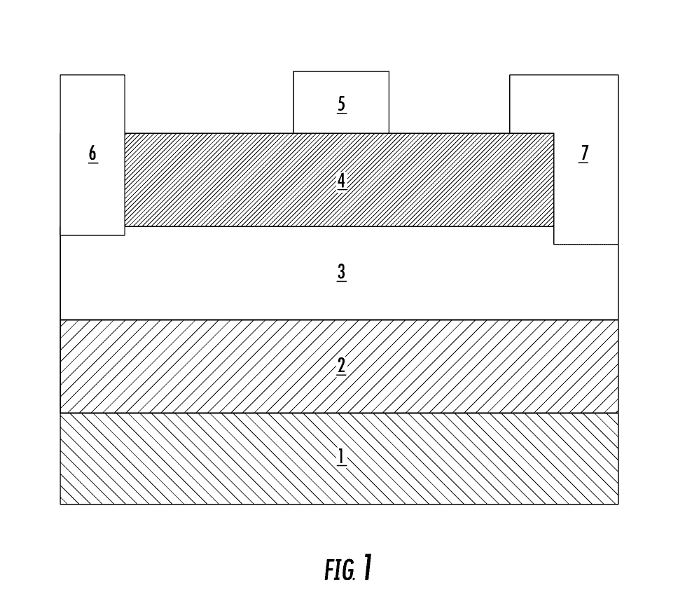

FIG. 1 is an overview of the architecture of an exemplary E-mode FET. This embodiment of an E-mode FET is comprised of a source contact 6, a gate contact 5, a drain contact 7, a substrate 1, one or more buffer layers 2, one or more channel layers 3, and one or more barrier layers 4.

In one embodiment, the substrate 1 can be comprised of III-nitride based material. In various other embodiments, the substrate 1 can be comprised of any other commercially available substrate material such as, for example, silicon (Si), silicon carbide (SiC), sapphire, and the like.

In one embodiment, the one or more buffer layers 2 can be comprised of semiconducting materials such as aluminum indium gallium nitride (AlInGaN) layer(s) with any compositions, doping or grading. In one embodiment, at least one of the one or more buffer layers 2 has an opposite conductivity of at least one of the one or more channel layers 3. For example, at least one of the one or more buffer layers 2 has p-type conductivity for an n-channel 3 HEMT, or vice-versa, wherein the conductivity of the one or more buffer layers 2 or the one or more channel layers 3 can be achieved using any implantation, doping or grading schemes. In one embodiment, the one or more channel layers 3 can be comprised of one or more III-N layers with any compositions, doping or grading.

In various embodiments, the one or more barrier layers 4 can be comprised of one or more III-N layers, of any composition, doping or grading, and/or one or more dielectric layers.

In various embodiments, the source contact 6, gate contact 5, and drain contact 7 can be comprised of, for example, metals such as Titanium, Aluminum, Nickel, Platinum, Gold and the like, or even highly doped semiconducting material such as the aluminum indium gallium nitride (AlInGaN) layers.

Though the FET can be fabricated using any known or later-developed techniques, in various embodiments each of the substrate 1, one or more buffer layers 2, one or more channel layers 3, and one or more barrier layers 4, can be epitaxially grown during the epi-growth or added using other regrowth and/or fabrication techniques. The source contact 6, gate contact 5, and drain contact 7 can be fabricated using any known or later-developed techniques.

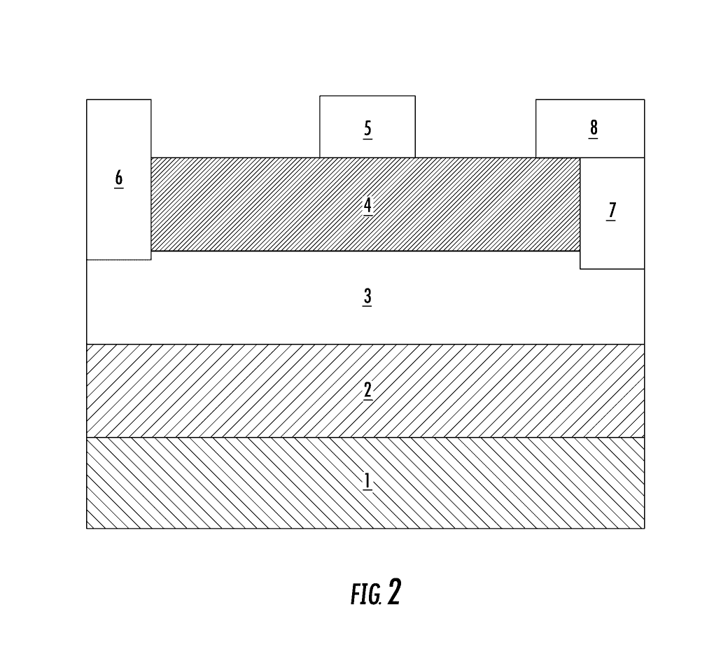

FIG. 2 illustrates the architecture of an exemplary E-mode FET, further comprising one or more drain field plates 8. In various embodiments as shown herein, the one or more drain field plates 8 can be comprised of one or more layers deposited above the drain contact 7, wherein the drain field plate 8 reduces a peak electric field in the one or more channel layers 3. In various aspects, the one or more drain field plates 8 can be comprised of metal and/or doped semiconductor materials. In one embodiment, the one or more drain field plates 8 can be comprised of one or more layers. One or more drain field plate layers can be integrated over the drain contact 7 using any metal deposition techniques, such as evaporation and sputtering. Different metal layers may be designed and interconnected with the drain contact 7 using any device processing techniques, and may be separated by dielectric layers using any deposition techniques. Vias can be used to connect the metal layers of the one or more drain field plates 8 with the drain contact 7. Similarly, drain field plate layers comprised of semiconducting material can be epitaxially grown during the epi-growth or added using other regrowth and/or fabrication techniques. The semiconductor drain field plate layers can be doped or composition-graded using any implantation, doping or grading schemes. Vias may also be used to connect the semiconductor layers of the one or more drain field plates 8 with the drain contact 7.

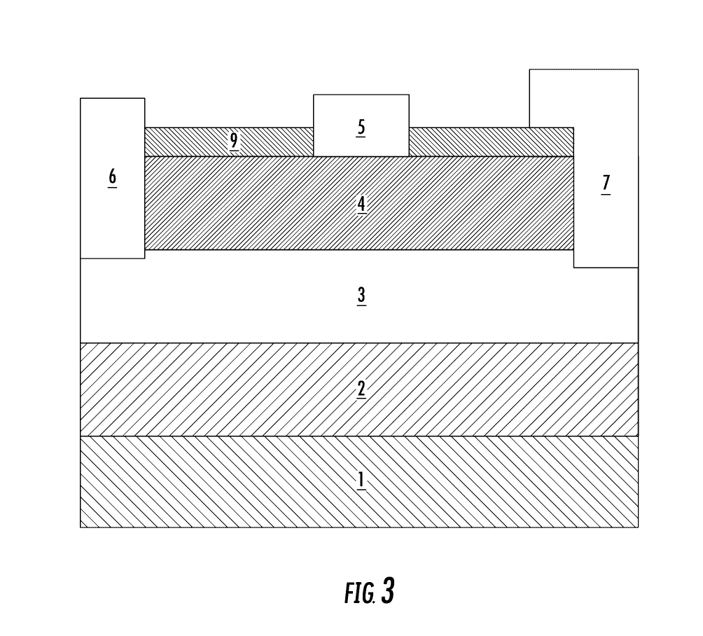

FIG. 3 illustrates the architecture of an exemplary E-mode FET, further comprising one or more dielectric layers 9. As shown in FIG. 3, the one or more dielectric layers 9 are located between the source 6 and gate 5 contacts and between the gate 5 and drain 7 contacts, on top of the one or more barrier layers 4. In the embodiment of FIG. 3, the drain contact 7 comprises an overhang structure that at least partially overlaps the one or more dielectric layers 9, extending into an access region towards the gate 5 or source 6 contacts.

FIG. 4 illustrates the architecture of an exemplary E-mode FET; further comprising one or more dielectric layers 9 and one or more drain field plates 8. In the embodiment shown in FIG. 4, at least one of the one or more drain field plates 8 comprises an overhang structure that at least partially overlaps the drain contact 7 and the one or more dielectric layers 9, extending into an access region towards the gate 5 or source 6 contacts.

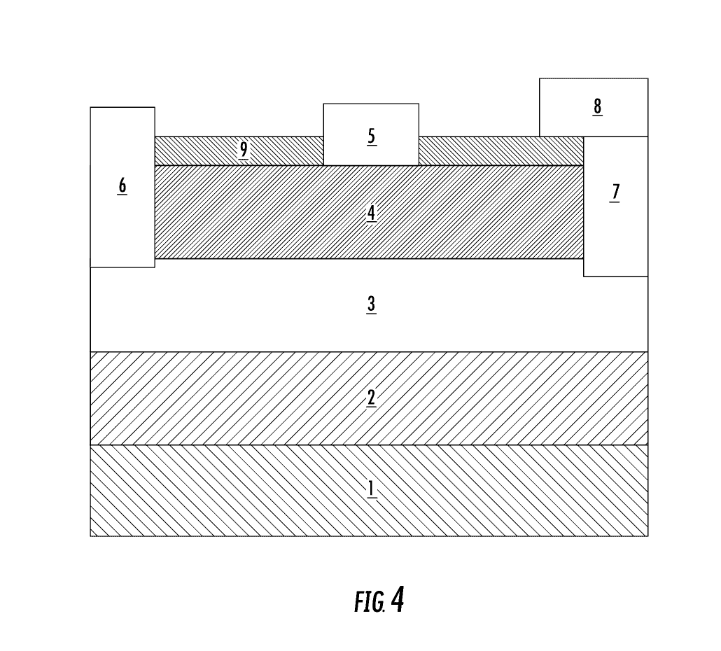

FIG. 5 illustrates the architecture of an exemplary E-mode FET, further comprising one or more dielectric layers 9. As shown in FIG. 5, the one or more dielectric layers 9 are located between the source 6 and gate 5 contacts and between the gate 5 and drain 7 contacts, on top of the one or more barrier layers 4. In the embodiment of FIG. 5, the drain contact 7 comprises a two-step overhang structure that at least partially overlaps the one or more dielectric layers 9, extending into an access region towards the gate 5 or source 6 contacts.

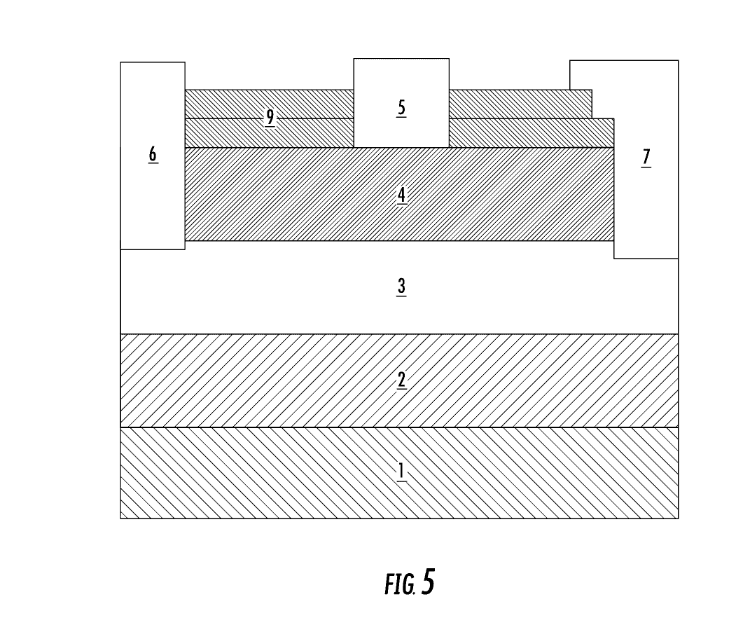

FIG. 6 illustrates the architecture of an exemplary E-mode FET; further comprising one or more dielectric layers 9 and one or more drain field plates 8. In the embodiment shown in FIG. 6, at least one of the one or more drain field plates 8 comprises a two-step overhang structure that at least partially overlaps the drain contact 7 and the one or more dielectric layers 9, extending into an access region towards the gate 5 or source 6 contacts.

FIG. 7 illustrates the architecture of an exemplary E-mode FET; further comprising one or more dielectric layers 9 and one or more drain field plates 8. In the embodiment shown in FIG. 7, at least one of the one or more drain field plates 8 comprises an overhang structure that at least partially overlaps the drain contact 7 and the one or more dielectric layers 9, extending into an access region towards the gate 5 or source 6 contacts. Further comprising the embodiment of FIG. 7 is a via that is used to connect the one or more layers of the drain field plates 8 with the drain contact 7.

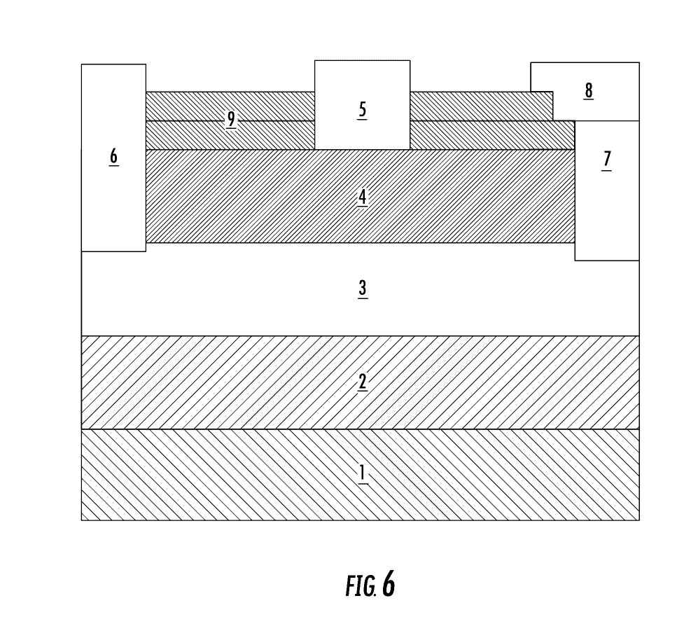

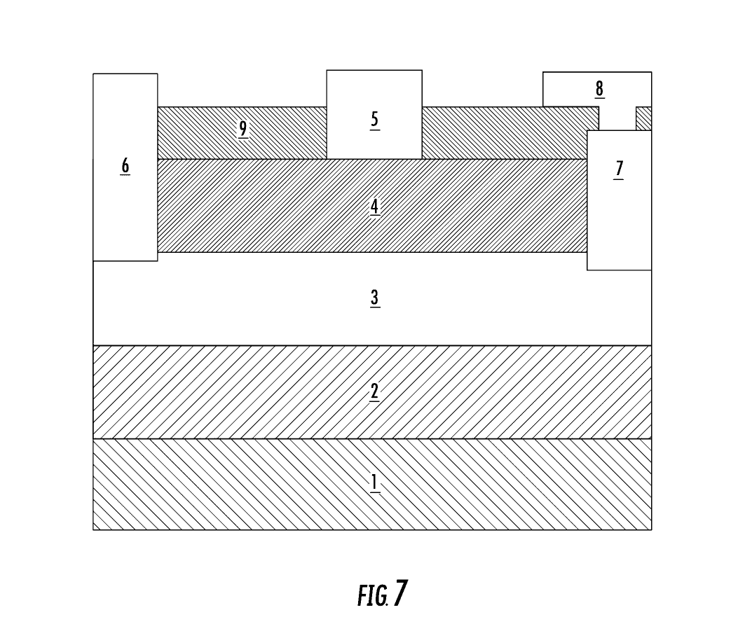

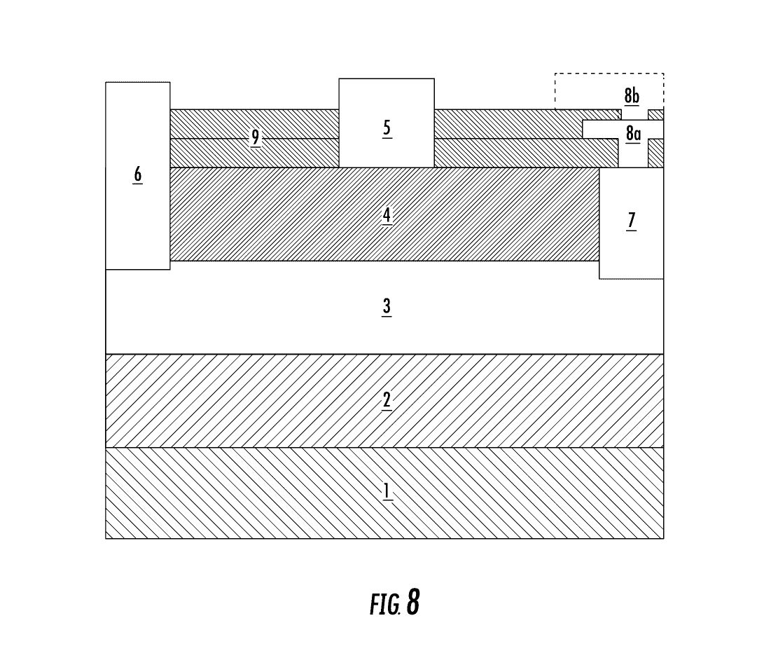

FIG. 8 illustrates the architecture of an exemplary E-mode FET; further comprising one or more dielectric layers 9 and one or more drain field plates 8. In the embodiment shown in FIG. 8, at least one of the one or more drain field plates 8 comprises an overhang structure that at least partially overlaps the drain contact 7 and the one or more dielectric layers 9, extending into an access region towards the gate 5 or source 6 contacts. In this embodiment, the overhang structure of the one or more drain field plates 8b extends over at least one layer of at least one of the drain field plates 8a and comprises at least one additional field plate layer 8a buried under one or more dielectric layers 9. Further comprising the embodiment of FIG. 8 are vias that is used to connect the one or more layers of the drain field plates 8a, 8b with the drain contact 7.

As shown in FIGS. 1-8, various embodiments of one or more drain field plates 8 include those with no overhang structures, embodiments with overhang structures that extend over at least one layer of one or more dielectric layers 9, embodiments with overhang structures that extend over at least one layer of at least one of the drain field plates 8, embodiments that comprise additional field plate layers buried under one or more dielectric layers 9; and embodiments with at least one of the one or more drain field plates 8 separated from the drain contact 7 using one or more dielectric layers 9 and interconnected with the drain contact 7 using one or more vias. In other embodiments, at least one of the one or more drain field plates 8 is comprised of any number of drain field plate layers 8a, 8b, etc. and dielectric layers 9 cascaded over the drain contact 7. These are examples of the various configurations of a FET that further comprise a drain field plate 8 and are not intended to be exhaustive or restrictive.

FIGS. 9, 10, and 11 are examples of contours illustrating device operational electric field in the x-direction with (FIG. 9) no drain field plates; (FIG. 10) one drain field plate; and (FIG. 11) two drain field plates. As shown in FIGS. 9, 10, and 11, all units are in microns; LGD=4 microns; VGD=200V. The device was simulated using Silvaco Atlas (Silvaco, Inc., Santa Clara, Calif.).

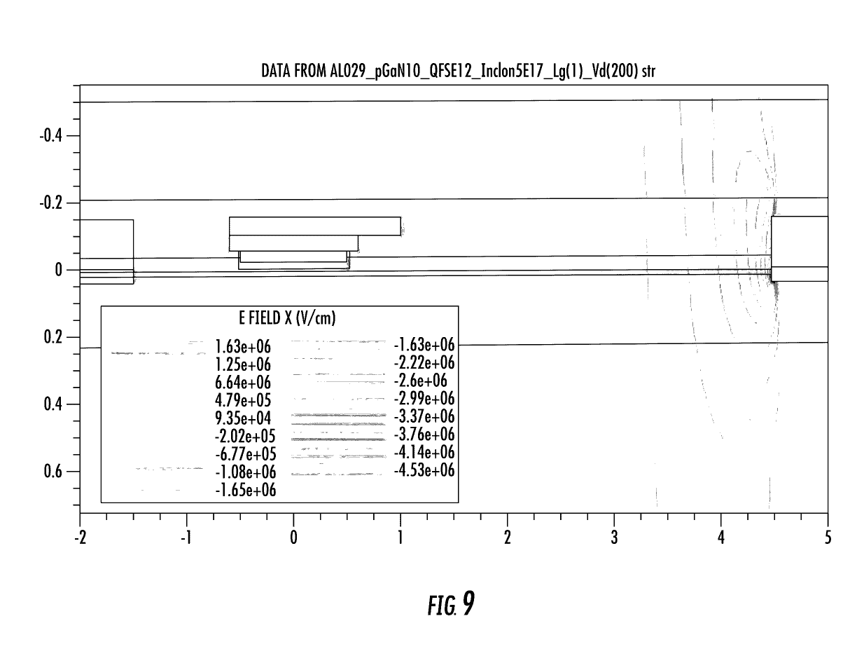

FIG. 12 is an example of a simulated device operational electric field across a two-dimensional electron gas (2DEG) channel in x-direction showing a peak reduction with the use of drain field plates; units MV/cm; VGD=200V. The blue or solid line represents no drain field plates; the brown or small dashed line represents one drain field plate; and the green or larger dashed line with intervening vertical slashes represents two drain field plates.

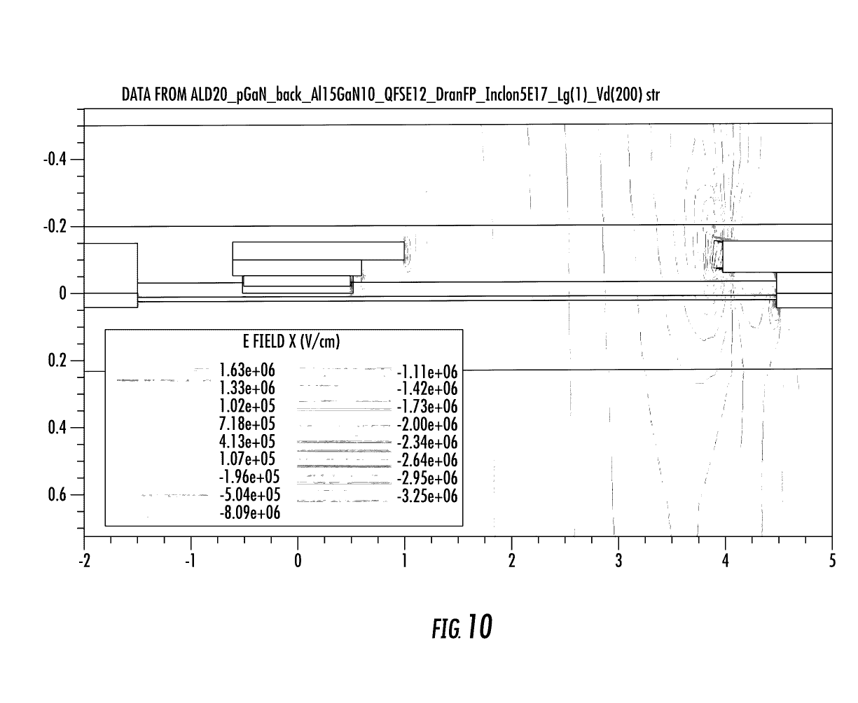

FIG. 13 illustrates an exemplary enhancement mode high electron mobility transistor (HEMT) comprising of a substrate 1301, one or more buffer layers 1302 (which can be either p-type of n-type buffers), one or more channel layers 1303, and one or more barrier layers 1304. As shown in FIG. 13, the HEMT may optionally comprise one or more dielectric layers 1305. In one aspect, one or more of the substrate 1301, the one or more buffer layers 1302, the one or more channel layers 1303, the one or more barrier layers 1304 and the one or more (optional) dielectric layers 1305 can be epitaxially grown during the epi-growth or using other regrowth and/or fabrication techniques. The HEMT structure shown in FIG. 13 can further include other metal connections and field plates such as one or more of a source contact, a gate contact, and a drain contact connected to any electrode using one or more growth and/or fabrication techniques.

As shown in FIG. 13, the substrate 1301 can be comprised of a Nitride-based material, or any other commercially available substrate, such as Si, SiC, and Sapphire, etc. The buffer layer 1302 can be comprised of one or more AlInGaN layers with any compositions, doping or polarization-grading. The buffer layer 1302 is comprised of opposite conductivity type layers, for example the buffer layer 1302 will be a p-type layer for an n-channel HEMT and an n-type layer for a p-channel HEMT. Desired conductivity of the buffer layer 1302 can be achieved using techniques such as ion-implantation, impurity doping, polarization-grading, or a combination of one of more methods. The opposite conductivity layers of the buffer layer 1302 can exist as grown, or be patterned under the Gate and/or Source using any implantation, regrowth and/or fabrication techniques. The opposite conductivity layers of the buffer layer 1302 can be contacted with an ohmic contact using any fabrication techniques, wherein the contact can be used as a separate electrode, or connected to one or more device electrodes, namely the source contact, the drain contact, the gate contact and a body contact. The ohmic contact to the opposite conductivity layers of the buffer layer 1302 can be contacted from the top, side or bottom of the device using fabrication techniques including lithography, via(s), and wire bonding. In other embodiments, the ohmic contact to the opposite conductivity layers of the buffer layer 1302 can be contacted from the top, side or bottom of the device with the use of tunnel junction layer(s) to inject carriers. The method to contact the opposite conductivity layers of the buffer layer 1302 can include, but not limited to formation of via(s) through the substrate, formation of via(s) through the top epi of the device, or flip chip method wherein the substrate is removed and the contacts are then formed.

The channel layer 1302 of the HEMT can be comprised of one or more III-N layers with any compositions, doping or grading. The barrier layer 1304 can be comprised of one or more III-N layers (any compositions, doping or grading) and/or one or more dielectric layers 1305. For example, the barrier layer 1304 can be comprised of, but not limited to one or more III-N layers, capped with composite dielectric layers (composed of one or more dielectric materials) 1305. In one aspect, the barrier layer 1304 can have additional layers added monolithically under the Gate using interconnects, such as metal or tunnel junction layer(s).

The drain field plate of the HEMT shown in FIG. 13 can be comprised of one or more layers (metal and/or doped semiconductor) deposited above the drain contact, wherein the field plate is designed to reduce the peak electric field in the channel. The drain field plate can partially or fully overlap with the drain contact, extending in the access region towards the gate or source contacts. Such overhang structures may also extend over and comprise of additional field plate layers buried under one or more dielectric layers. The drain field plate may be separated from the drain using one or more dielectric layers and interconnected using one or more vias. The drain field plate can be comprised any number of such repetitions of dielectric/field plate layers cascaded over the drain contact.

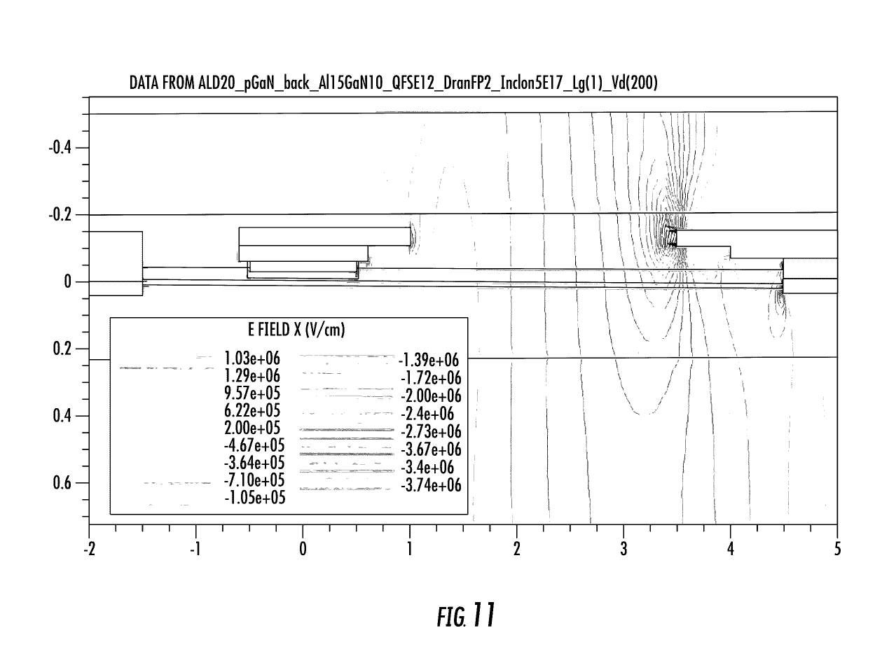

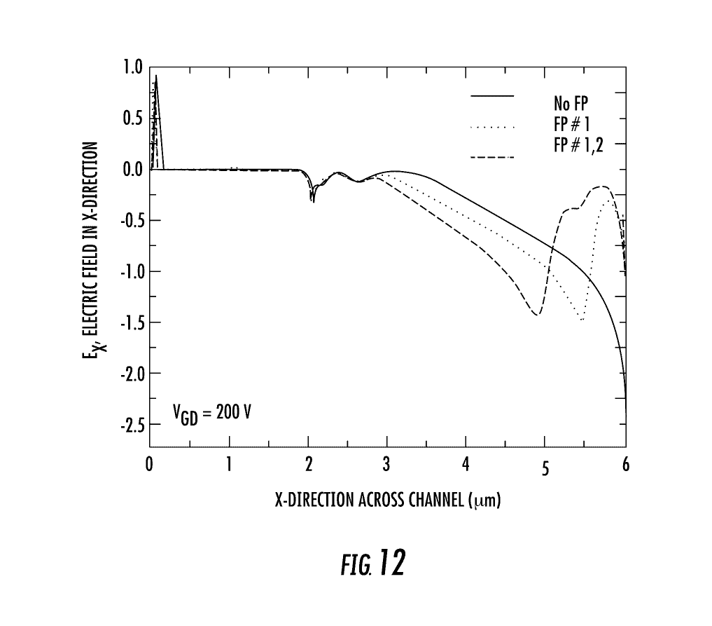

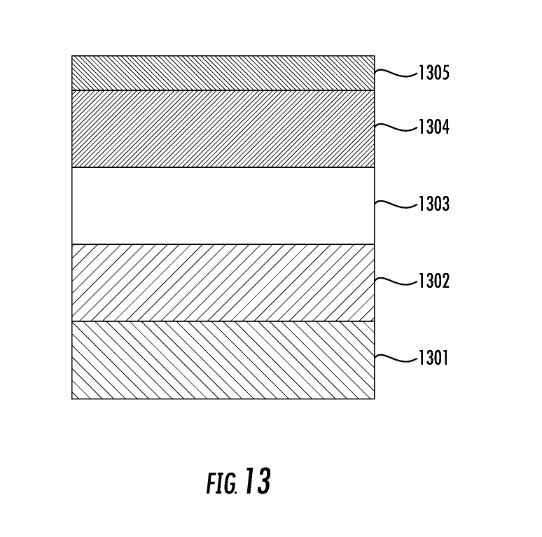

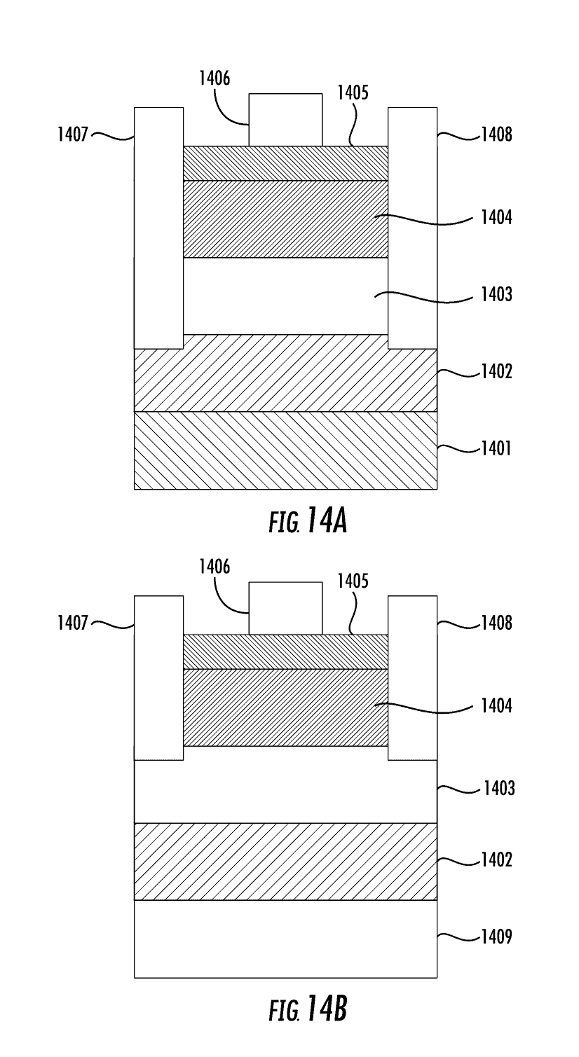

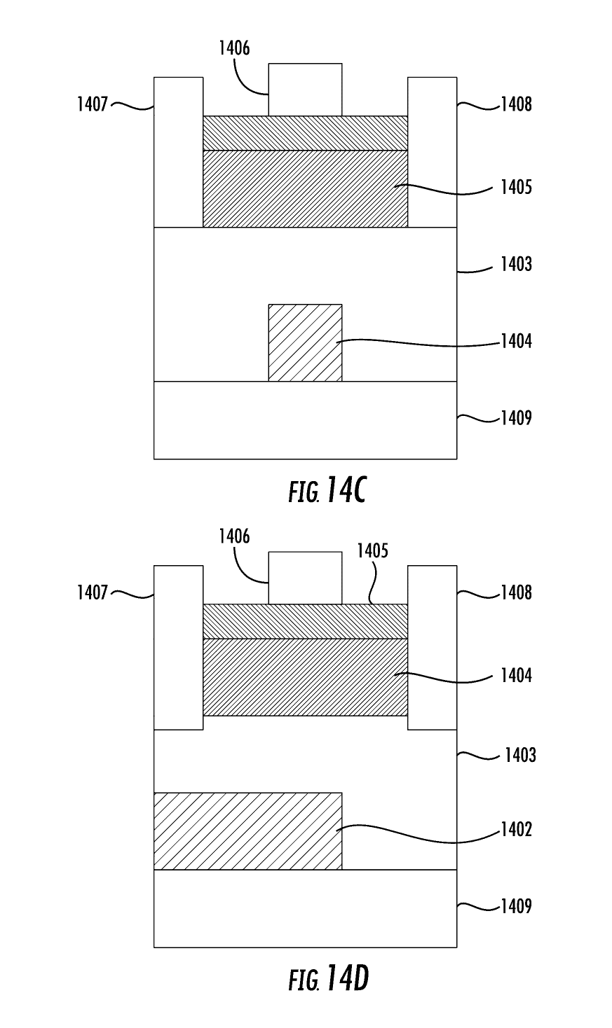

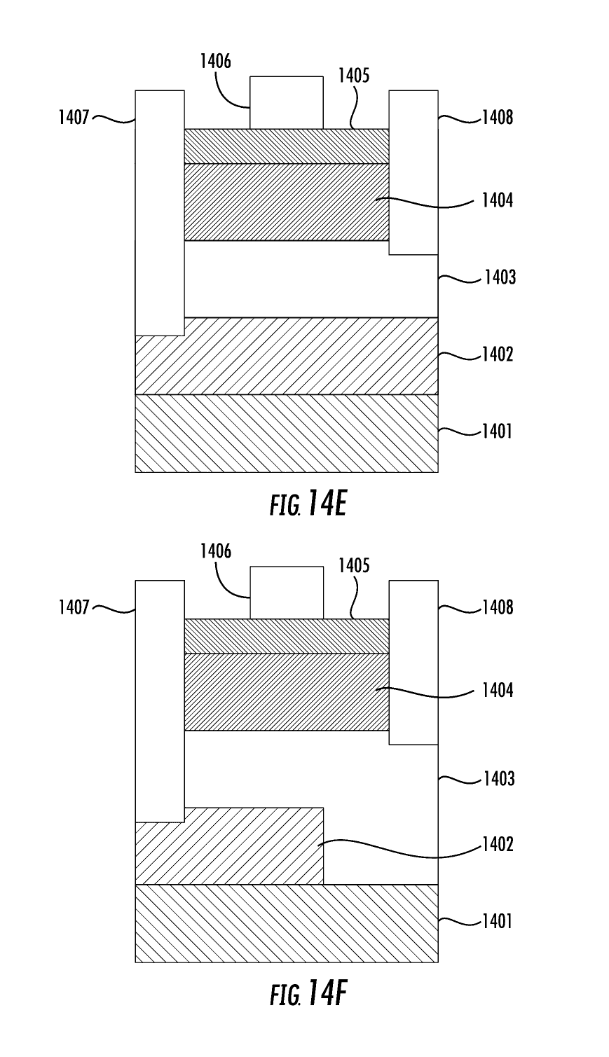

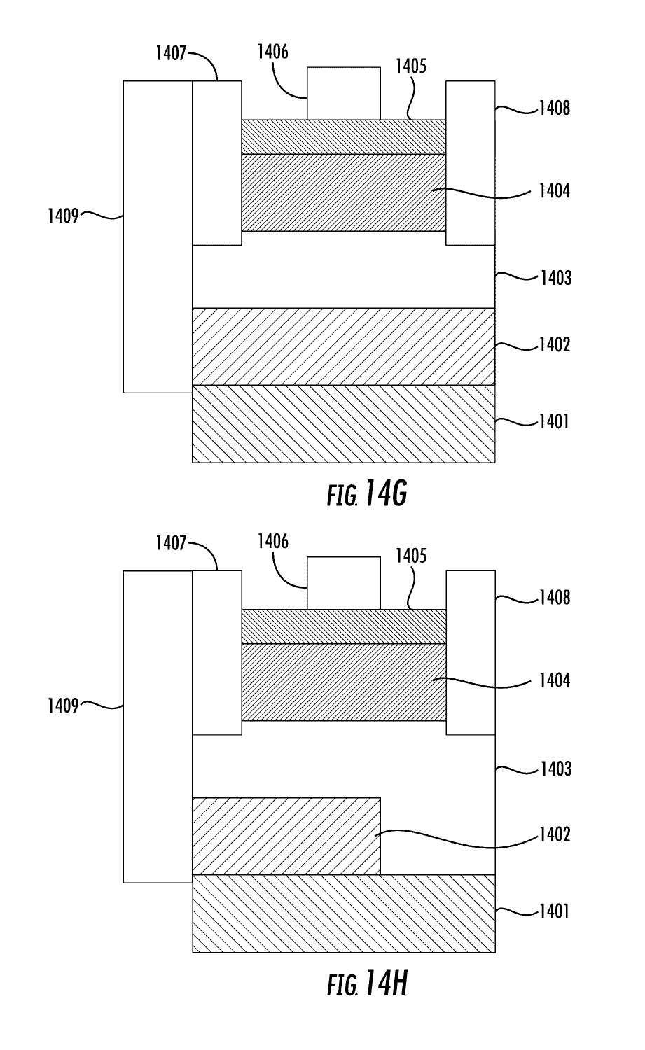

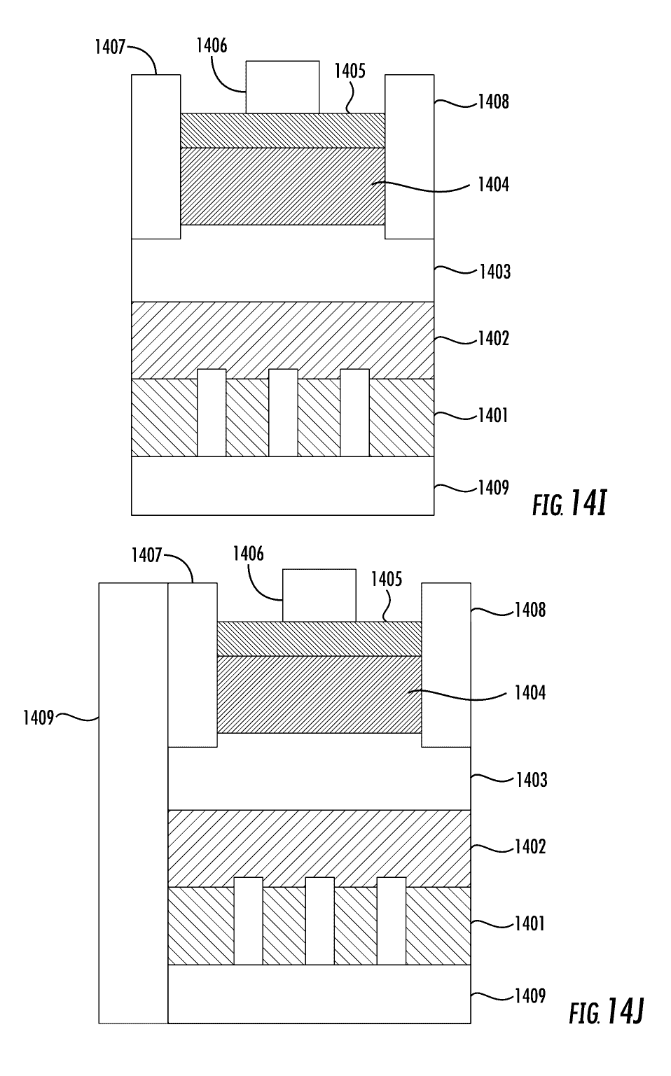

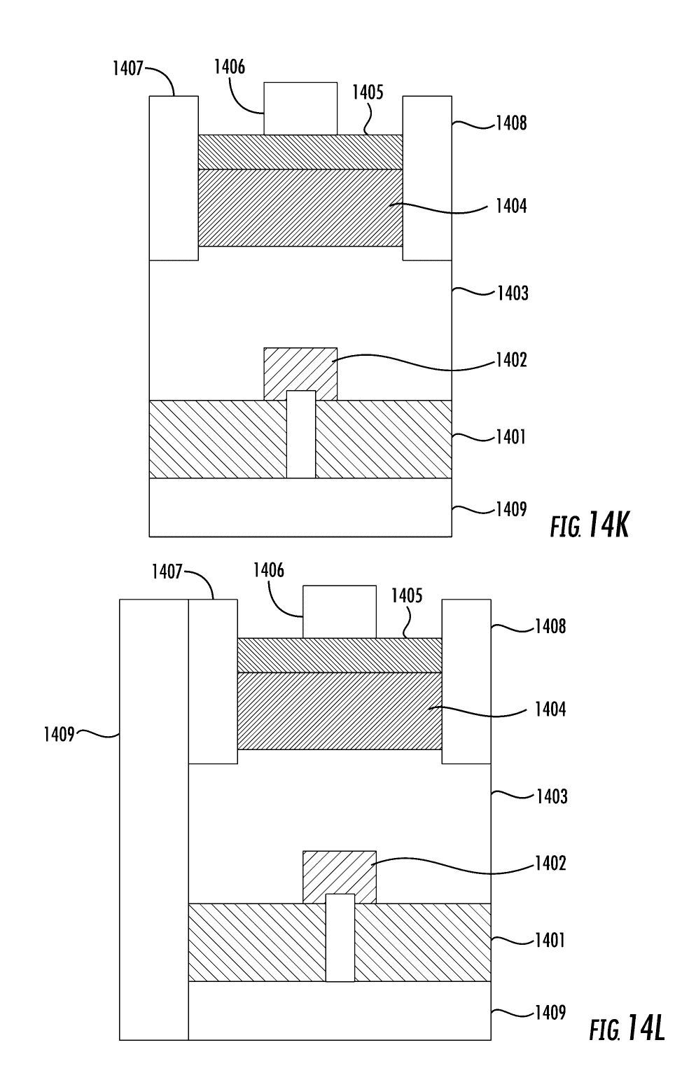

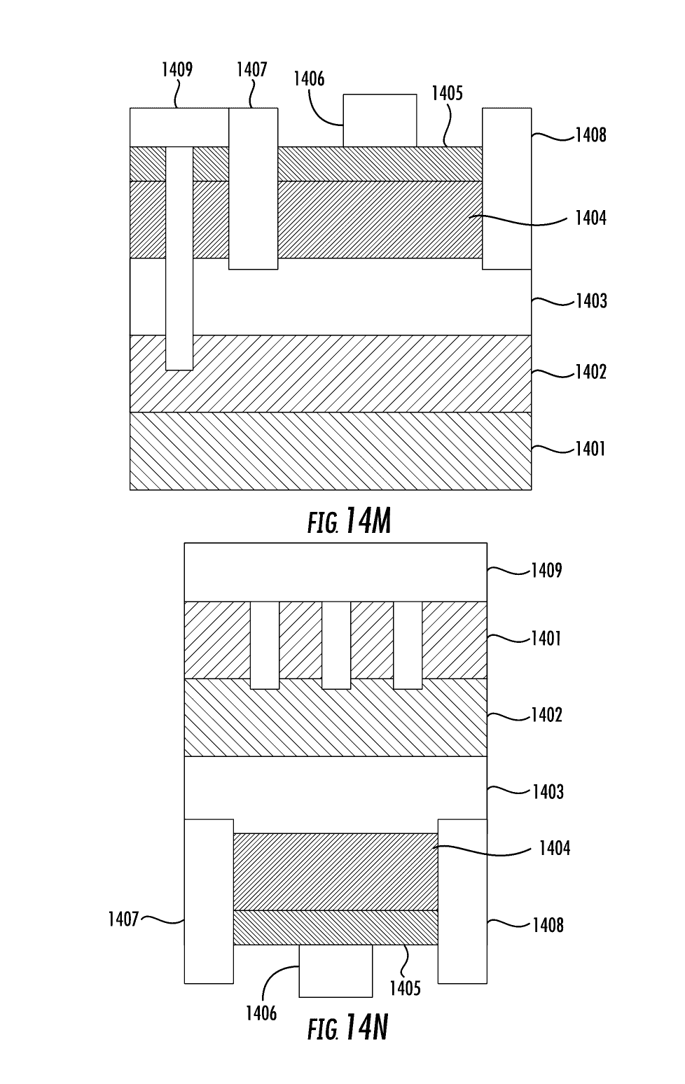

FIGS. 14A-14N illustrate various non-limiting designs and configurations of a HEMT. It is to be noted in these figures that these embodiments are comprised of a substrate 1401, one or more buffer layers 1402 (which can be either p-type of n-type buffers), one or more channel layers 1403, and one or more barrier layers 1404. Alternatively or optionally, the design or configuration may comprise a contact 1409 to the buffer layer 1402. If the buffer layer 1404 is p-type, the contact 1409 is p-type. If the buffer layer is n-type, then the contact 1409 is n-type. As shown in FIGS. 14A-14N, the HEMT may optionally comprise one or more dielectric layers 1405. As described in relation to FIG. 13, the one or more of the substrate 1401, the one or more buffer layers 1402, the one or more channel layers 1403, the one or more barrier layers 1404 and the one or more (optional) dielectric layers 1405 can be epitaxially grown during the epi-growth or using other regrowth and/or fabrication techniques. The HEMT structure shown in FIGS. 14A-14N can further include other metal connections and field plates such as one or more of a source contact 1407, a gate contact 1406, and a drain contact 1408 connected to any electrode using one or more growth and/or fabrication techniques.

The HEMT designs and configurations of FIGS. 14A-14N can comprise an n-channel FET or a p-channel FET. If an n-channel FET, the channel layer 1403 is n-type material and the buffer layer 1402 and any contact 1409 with the buffer layer 1402 is p-type material. Alternatively, If a p-channel FET, the channel layer 1403 is p-type material and the buffer layer 1402 and any contact 1409 with the buffer layer 1402 is n-type material.

FIG. 15 illustrates an energy band diagram of embodiments of the HEMT of FIGS. 13-14N in the equilibrium state and the on state where C_{CAP} and C_{CHANNEL} are the capacitances of the cap or barrier layer 1304, 1404 and the channel 1303, 1403, respectively.

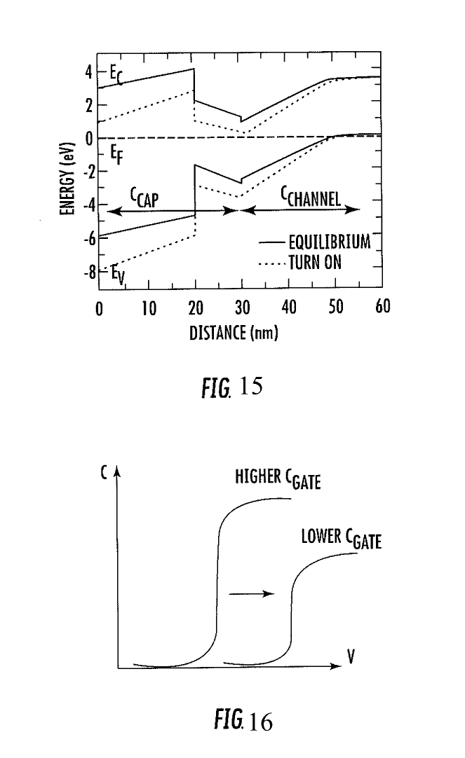

FIG. 16 illustrates a positive shift in the threshold voltage by lowering gate capacitance in an embodiment with a p-type buffer.

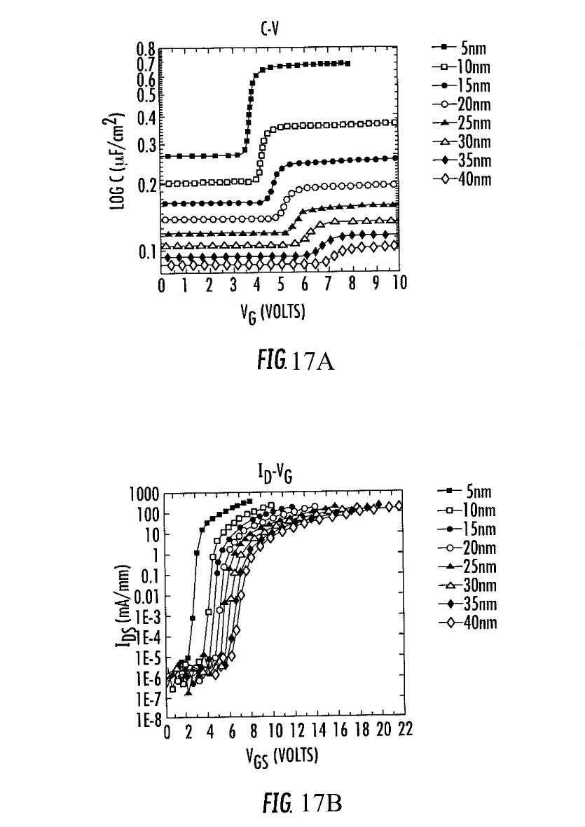

FIGS. 17A and 17B illustrate simulated C-V and I_{D}-V_{G} transfer characteristics of embodiments of the disclose HEMT of FIGS. 13-14N with varying dielectric (cap) thicknesses (5 nm to 40 nm), demonstrating enhancement of threshold voltage with increasing dielectric thickness.

Nitride power electronics is a fast growing industry, and the continuous extensive research on nitride HEMTs has been able to achieve enhancement-mode operation with low threshold voltage. E-mode FETs with doped buffers can achieve high positive threshold voltages. Such devices; however, experience large operational electric fields near the drain contact. Drain field plates as described herein modify the electric field profile in the channel and improve the device's performance. While embodiments of this Invention particularly impact the nitride power electronics applications; it can be used with any material system.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. An enhancement mode field effect transistor (E-mode FET) comprising:
a source contact;
a gate contact;
a drain contact;
a substrate;
one or more buffer layers;
one or more channel layers;
one or more cap layers, wherein the one or more cap layers are comprised of one or more barrier or dielectric layers; and
one or more drain field plates.

2. The E-mode FET of claim 1, wherein each of the substrate, one or more buffer layers, one or more channel layers, one or more barrier layers, and one or more drain field plates are epitaxially grown during an epi-growth process.

3. The E-mode FET of claim 1, wherein each of the substrate, one or more buffer layers, one or more channel layers, one or more barrier layers, and one or more drain field plates are added using regrowth fabrication techniques.

4. The E-mode FET of claim 1, wherein the substrate is comprised of III-nitride based material.

5. The E-mode FET of claim 1, wherein the substrate is comprised of silicon (Si), silicon carbide (SiC), or sapphire.

6. The E-mode FET of claim 1, wherein at least one of the one or more buffer layers are comprised of aluminum indium gallium nitride (AlInGaN).

7. The E-mode FET of claim 6, wherein the at least one of the one or more buffer layers comprised of aluminum indium gallium nitride (AlInGaN) has any mole-fraction composition, doping or composition-grading.

8. The E-mode FET of any of claim 1, wherein at least one of the one or more buffer layers has an opposite conductivity as at least one of the one or more channel layers.

9. The E-mode FET of claim 8, wherein at least one of the one or more buffer layers has p-type conductivity and at least one of the one or more channel layers has n-type conductivity.

10. The E-mode FET of claim 8, wherein at least one of the one or more buffer layers has n-type conductivity and at least one of the one or more channel layers has p-type conductivity.

11. The E-mode FET of claim 8, wherein the one or more buffer layers having an opposite conductivity as the at least one of the one or more channel layers can be added epitaxially, or be patterned under the gate contact or the source contact using implantation, regrowth or fabrication techniques.

12. The E-mode FET of claim 8, wherein the one or more buffer layers having an opposite conductivity as the at least one of the one or more channel layers are contacted with an ohmic contact, wherein the ohmic contact can be used as a separate electrode or connected to one or more of the source contact, the drain contact, the gate contact, or a body contact.

13. The E-mode FET of claim 12, wherein the ohmic contact can be contacted from the top, side or bottom of the device using fabrication techniques including lithography, one or more vias, and wire bonding, or with the use of one or more tunnel junction layers to inject carriers.

14. The E-mode FET of claim 12, wherein the one or more buffer layers having an opposite conductivity as the at least one of the one or more channel layers are contacted using one or more of formation of vias through the substrate, formation of vias through the cap layer, or a flip chip method wherein the substrate is removed and the contact is then formed.

15. The E-mode FET of claim 1, wherein at least one of the one or more channel layers is comprised of III-N materials.

16. The E-mode FET of claim 11, wherein the at least one of the one or more channel layers comprised of III-N materials has any mole-fraction composition, doping or composition-grading.

17. The E-mode FET of claim 1, wherein at least one of the one or more barrier layers is comprised of III-N materials.

18. The E-mode FET of claim 17, wherein the at least one of the one or more barrier layers comprised of III-N materials has any mole-fraction composition, doping or composition-grading.

19. The E-mode FET of claim 1, wherein at least one of the one or more cap layers is comprised of dielectric materials.

20. The E-mode FET of claim 11, wherein at least one of the one or more cap layers is comprised of one or more metal-dielectric-metal diodes, or one or more semiconductor PN or PIN diodes cascaded using epitaxial growth or metal/dielectric deposition techniques.

21. The E-mode FET of claim 20, wherein at least one of the one or more cap layers is comprised of one or more semiconductor PN or PIN diodes cascaded using tunnel junction (TJ) interconnects over an E-mode FET using epitaxial growth techniques including Molecular Beam Epitaxy and Metal Organic Chemical Vapor Deposition.

22. The E-mode FET of claim 1, wherein the one or more drain field plates are comprised of one or more layers deposited above the drain contact, wherein the drain field plate reduces a peak electric field in the one or more channel layers.

23. The E-mode FET of claim 1, wherein the one or more drain field plates are comprised of metal materials.

24. The E-mode FET of claim 1, wherein the one or more drain field plates are comprised of doped semiconductor materials.

25. The E-mode FET of claim 1, wherein the one or more drain field plates are comprised of layers of metal and doped semiconductor materials.

26. The E-mode FET of claim 1, wherein the one or more drain field plates are comprised of any number of drain field plate layers or dielectric layers cascaded over the drain contact or connected to any one of the source contact, a body contact, or the gate contact.

27. The E-mode FET of claims 1, wherein the one or more drain field plates comprise an overhang structure that at least partially overlaps the drain contact, extending into an access region towards the gate or source contacts.

28. The E-mode FET of claim 27, wherein the overhang structure extends over at least one layer of at least one of the drain field plates.

29. The E-mode FET of claim 1, wherein the one or more drain field plates comprise additional field plate layers buried under one or more dielectric layers.

30. The E-mode FET of claims 1, wherein the one or more drain field plates are separated from the drain contact using one or more dielectric layers and interconnected with the drain contact using one or more vias.
